(19) United States
(12) Patent Application Publication
(10) Pub. No.: US 2011/0024775 A1
(43) Pub. Date: Feb. 3, 2011

(54) Methods for and devices made using multiple stage growths

(75) Inventors: Scott M. Zimmerman, Basking Ridge, NJ (US); Karl W. Beeson, Princeton, NJ (US); William R. Livesay, San Diego, CA (US); Richard L. Ross, Del Mar, CA (US)

Correspondence Address: Goldeneye, Inc.;Suite 233, 9747 Businesspark Avenue, San Diego, CA, 92131, US

(73) Assignee: Goldeneye, Inc.

(21) Appl. No.: 12/462,277

(22) Filed: Jul. 31, 2009

(51) Int. Cl. H01L 29/06; H01L 33/00; H01L 33/02; H01L 31/18; H01L 29/12

(52) U.S. Cl. 257/94; 257/183; 438/47; 438/94; 257/613; 257/629; 257/E33.005; 257/E33.013; 257/E31.032; 257/E29.068; 257/E29.005

(57) ABSTRACT

Surface modification of individual nitride semiconductor layers occurs between growth stages to enhance the performance of the resulting multiple layer semiconductor structure device formed from multiple growth stages. Surface modifications may include, but are not limited, to laser patterning, lithographic patterning (with the scale ranging from 10 microns to a few angstroms), actinic radiation modifications, implantation, diffusional doping and combinations of these methods. The semiconductor structure device has enhanced crystal quality, reduced phonon reflections, improved light extraction, and an increased emission area. The ability to create these modifications is enabled by the thickness of the HVPE growth of the GaN semiconductor layer.

### BACKGROUND OF THE INVENTION

The present solid state general illumination market is dominated by blue gallium nitride (GaN) light emitting diodes (LEDs) and powdered phosphors. Efficient GaN LEDs have been developed which are then used to excite powder phosphors to form white light sources. This approach is used mainly because of the poor efficiency of nitride LEDs for wavelength longer than 500 nm. While aluminum indium gallium phosphide (AlInGaP) does provide an efficient LED at wavelength greater than 620 nm, it is more temperature sensitive and can not handle high drive currents as well as nitrides. The result is the so-called “green gap” which has forced the use of powdered phosphors plus blue LEDs even though they offer a less than optimum solution.

Powder phosphor technology dates back over 100 years and is primarily based on solid state processing of compounds. A variety of inorganic materials are mixed in powder form, fired or sintered in a variety of manners, and then ground into powders. While this approach is cost effective, it is difficult to create high purity luminescent materials and to prevent the introduction of contaminates. There are also limitations on efficiency relating to Stokes shift and range of materials, which absorb within the blue spectrum, where nitride LEDs are most efficient. In addition, powdered phosphors are limited by their low thermal conductivity which effects color stability, efficiency, and peak output levels. Also, many of the highest efficiency phosphors are moisture sensitive.

Novel luminescent materials overcome many of the limitations of powder phosphor approaches. Even so, the ability to enhance the emission range and efficiency of nitride LEDs over the entire visible spectrum is still needed to realize efficient solid state lighting sources. If the range of efficient operation could be extended in nitrides, more efficient and higher color rendering index (CRI) white light sources could be created. The key to enhancing the performance of nitrides are reducing dislocations defects and lower stresses within the layers decrease thermal conductivity and limit high current operation and life.

In addition, the need exists for improving crystal quality in nitride alloys. In particular, the ability to grow high quality high concentration indium InGaN is needed if efficient long wavelength nitride LEDs are to be realized.

Alternately, nitrides are being used increasingly in RF, optoelectronics, solar cells, and power devices based on their high temperature properties and improved electrical properties. In all these cases, the formation of higher quality nitride alloys is important. In a similar manner to LEDs, solar cells in particular, could benefit dramatically from higher quality high concentration Indium InGaN. This would greatly extend the usable range of the nitrides to cover the majority of the solar spectrum.

Solid state lighting, high powered switches and high powered RF devices also require very low thermal impedance designs in order to enable many of the applications envisioned for nitrides. In the case of lighting, high flux levels are required to meet the lumens/mm2 requirements of general illumination. Similar requirements exist for RF, power and optoelectronics applications. Nitrides in particular offer the opportunity to create devices with power densities exceeding 10 watt/mm2. Recent evidence suggests that high purity low dislocation GaN has much higher thermal conductivity than previously reported. However, nitrides lack a cost effective native nitride substrate, unlike silicon. Even if such a substrate existed, the thickness of the bulk substrate would have to be reduced via some type of thinning means to create useful devices due to the finite conductivity of any material, even diamond. As such, 400 micron bulk nitride wafers would be typically thinned to less than 100 microns in most high powered applications. The use of relatively thick (15 to 200 micron) HVPE grown templates offer an alternative to bulk substrates, while still offering many of a bulk substrate's advantages. After separation or removal of the non-native growth substrate (typically sapphire, SiC, silicon, or glass), a die with the appropriate thickness for high powered applications is formed. Previous patent applications from the present inventors have demonstrated free-standing all-nitride devices with thickness ranging between 15 microns and over 130 microns. 1 cm×1 cm devices have been demonstrated with sufficient mechanical integrity for die attach and pick and place operations. Unlike bulk templates, these devices do not require any subsequent thinning steps and, unlike thin templates, these devices do not require waferbonding to supporting substrate. The need however still exists for techniques and methods, which take further advantage of the mechanical, thermal and growth benefits of thick templates.

As an example, the impact of the thermal limitations of thin templates are discussed further. Typically non-native submounts are used to both grow and support thin nitride layers that remained mounted and attached on the non-native substrate. Alternately, after growth on a non-native substrate, the thin nitride layers are transferred to another support submount via waferbonding techniques. In either case, multiple thermal boundaries, both epitaxial and non-epitaxial, are created by the various coatings and growths.

Even an epitaxially grown interface can create significant thermal boundary resistance between semiconductor layers. Surprisingly, these epitaxial boundaries represent the major thermal impedance for high powered semiconductor structure devices. A need exists for semiconductor structure fabrication methods and semiconductor structure devices, which overcome these thermal impedance limitations.

While a significant amount of the effort has gone into growing freestanding nitride wafers with low dislocation defects, the cost of this approach is very high. The present inventors have previously filed patent applications on the use of lifted thick nitride semiconductor structure devices based on thick HVPE layers and forming such thick all nitride devices using laser processing. The resulting all epitaxial semiconductor structure device offers the lowest thermal impedance performance for high powered semiconductor structure devices.

There are a number of reasons that improved nitrides are needed. As multi-wafer HYPE reactors become available, the cost of the HYPE templates will drop significantly. The present inventors have developed thick (greater than 10 microns thick) HVPE templates and have discovered a number of novel attributes that these thick HYPE templates provide.

This present invention discloses fabrication methods and semiconductor devices based on the use of thick HVPE templates to reduce phonon reflections, increase active area, improve extraction, improve indium incorporation, increase subsequent growth rates, and enhance crystal quality. While hybrid approaches based on separate HVPE/MOCVD reactors have been demonstrated previously, the use of thick HVPE templates greater than 10 microns thick are disclosed in the present invention, which enable free standing all nitride devices which take advantage of several previously unreported properties of thick templates. Using this technique, not only can the thermal impedance of the device be reduced by eliminating unnecessary thermal impedance boundary layers, but also improved crystal quality nitride alloys can be produced. Additionally, the ability to modify the surfaces of the thick HVPE template to enhance device performance is also disclosed. These attributes can be used to create more efficient long wavelength LEDs, lower thermal impedance devices, and enhanced performance solar cell, RF, optoelectronics and power devices.

### SUMMARY OF THE INVENTION

Thick doped or undoped nitride layers on a sapphire substrate have been developed using HVPE growth techniques. These layers range from 15 microns to over 150 microns in thickness. These thick nitride layers are optically smooth and exhibit less than 50 microns bow on a 2 inch diameter sapphire wafer 430 microns thick at room temperature. The bow limits enable higher yield during laser liftoff due to the finite depth of field of the laser liftoff system. These thick HVPE templates exhibit reduced surface stress and higher thermal conductivity than thinner templates, provide an epitaxial deposition ready surface, and are available in a variety of dopant concentrations and profiles through the thickness of the nitride layers. The wafers exhibit no backside nitride growth, which enables complete separation of the nitride layer from the sapphire growth substrate without the use of backside polishing. The GaN wafers exhibit an average alpha less than 1 cm⁻¹ for all thicknesses and Si doping levels less than 10¹⁹ for wavelengths greater than 395 nm. The formation of freestanding nitride templates with areas greater than 1 inch×1 inch have been demonstrated.

Templates based on nitride alloys of aluminum and indium have been developed as well which enables the formation of templates that have their absorption properties either shifted to short wavelengths, as in the case of aluminum gallium nitride (AlGaN) alloys, or longer wavelengths, based on indium gallium nitride (InGaN) alloys. Aluminum indium gallium nitride (AlInGaN) and other dilute nitrides can be used as templates. The nitride layers greater than 15 microns in thickness are crack free. Upon separation, the nitride layers are flexible and can be bent or flattened. 30 micron thick nitride layers 1 inch×1 inch have been formed that are flexible and can be conformed to a variety of surfaces ranging from flat to curve have a radius greater than 1 cm. The lamination of these layers can form plywood like structures.

The resulting layers and the freestanding devices made from these layers can be processed at elevated temperatures including, but not limited to, thermal annealing, brazing, soldering, subsequent regrowths, melt process within glasses, and bonding approaches. The attributes of the templates and layers formed from these templates and the templates and layers formed from these templates themselves are embodiments of this invention. The attributes of these templates and the layers made from these templates combined with the other parts of this invention can be used to form improved LEDs, solar cells, RF, and power devices.

While alternate growth methods are possible and are embodiments of this invention, the focus will be on HVPE due to lower cost, lower average alpha, and higher crystal quality compared to bulk, MOCVD, and MBE. The thick HYPE template can create higher quality nitride alloys compared to thinner templates. Even more preferred is the use of flexible freestanding all nitride templates based on laser liftoff of thick HVPE layers grown on sapphire growth substrates. In general, the use of thick HVPE templates creates higher efficiency LEDs due to the ability to create higher quality high indium concentration InGaN. The exact mechanisms, which lead to the improved InGaN growth, are unclear. While work from Berkeley on 5 and 15 micron MOCVD templates on sapphire indicates enhanced growth rates on thicker templates (which they attribute to lower surface stress in thick layers), their work was in the blue region of the spectrum and the MOCVD templates were cost prohibitive. Alternately, other authors have argued the opposite that increase stress within the wells increases indium incorporation. The present inventors have developed thick (greater than 15 microns) HYPE templates, which are cost effective, exhibit epitaxial deposition ready surfaces, reduced bow and low enough alpha to enable their use in this invention. Increased quality high indium InGaN can be grown on thick HYPE templates. Even more preferred is the use of flexible freestanding substantially all-nitride templates for increased quality high indium content InGaN.

A further advantage of having a thick nitride layer is the ability to make surface modifications on a reasonable scale both within the device and on an external surface to the device. The use of subwavelength surface modification is an embodiment but micron sized modifications or larger are preferred due to lower manufacturing costs. The removal of the thick nitride layer can create a freestanding device, both separately and in combination with the other disclosed inventions herein. These surface modifications can be on one side, both sides, and on edges of the templates. Surface modification on both sides of at least one flexible freestanding substantially all-nitride foil is a preferred embodiment of this invention.

Another focus of this invention is to disclose the methods of enhancing the performance of semiconductor structure devices on thick HYPE templates by using multiple growth stages. By separating the various growth layers into separate growth stages, more optimum reactor performance can be realized. As an example, presently a typical LED grown within a single MOCVD reactor requires that the MOCVD reactor first grow a low temperature nucleation, then grow a 2 to 3 micron thick Si doped GaN layer, followed by alternating layers of InGaN, GaN quantum wells typically 30 angstroms and 120 angstroms thick respectively, followed by 200 angstroms of AlGaN doped with Mg, followed by 1500 angstroms of Mg doped GaN. Reactor operating conditions vary drastically during this growth process. Even more importantly, the previous layers can contaminate the other layers due to memory within the reactor. This is especially true of Si and Mg.

A thick HVPE template can be directly loaded into a MOCVD reactor, the MQWs only can be grown, the wafer, tape, ribbon, foil, or fiber form factor of the thick HYPE template can be removed from the MOCVD reactor and put into a MOCVD, MO-HVPE, or HVPE reactor and the AlGaN barrier and GaN p Layer can be grown successfully. While template growth has been demonstrated for complete structures, the growth of just the quantum wells in one reactor followed by growth of the barrier and p layer in a separate reactor has not previously been demonstrated. Using this approach, the MQW MOCVD reactor can be tuned for optimum quantum well growth, and the barrier and p layers can be done in a reactor tuned for efficient incorporation of Mg and Aluminum as required by those layers. In addition, it is an embodiment of this invention that the most preferred is the use of HVPE to form the barrier and p layers due to lower alpha, ability to increase aluminum concentration while maintaining crystal quality, and ability to grow thicker higher crystal quality p type layers.

In addition, the use of multiple growth stages allows for the introduction of surface modification between growth stages. This approach is applicable to nitrides, dilute nitrides, various alloys and other high bandgap materials such a diamond. The use of these approaches are applicable to not only LEDs but laser diodes, power devices such as FET, HEMTs, optoelectronics, MEMS, solar cells, and RF devices. Surface modifications may include, but are not limited, to laser patterning, lithographic patterning (with the scale ranging from 10 microns to a few angstroms), actinic radiation modifications, implantation, diffusional doping and combinations of these methods. The results of these methods include, but are not limited, to enhancing crystal quality, reducing phonon reflections, creating light extraction, and creating an increased emission area. Similarly, these methods enable higher crystal quality growth and enhanced thermal performance devices for all semiconductor and electrical device applications. The ability to create these modifications is enabled by the thickness of the HVPE growth of the GaN semiconductor layer. It is most preferred that the thick nitride layer be greater than 15 microns and, even more preferred, that the thick nitride layer be greater than 30 microns. Surface modifications with feature depth to thick nitride layer thickness ratios greater than 0.1 are most preferred. Controlled atmospheres between, during, or after these growth interruptions can create these surface modifications. The combination of improved crystal quality due to the thick nature of the HYPE template and surface modifications of the layer prior to any of the growth steps is an embodiment of this invention. Surface modification can be on one or both sides of the HVPE template. A preferred embodiment is dual sided processing of at least one flexible freestanding substantially all-nitride template.

### BRIEF DESCRIPTION OF THE DRAWINGS

FIGS. 1A, 1B and 1C depicts typical prior art light emitting diode die configurations.

FIGS. 2A and 2B depicts vertical, all nitride epitaxial chips in both p contact up and p contact down configurations of the present invention.

FIG. 3 depicts an epitaxial growth process of a semiconductor structure device on a thick nitride substrate with an intermediate surface modification step between growths of the present invention.

FIG. 4 depicts an epitaxial growth process with a surface modification between the n layer and the active region of a light emitting diode structure of the present invention.

FIG. 5A depicts PL spectrum versus wavelength on a thick HVPE template. FIG. 5B depicts thickness and indium concentration versus wavelength on a thick HYPE template.

### DETAILED DESCRIPTION OF THE INVENTION

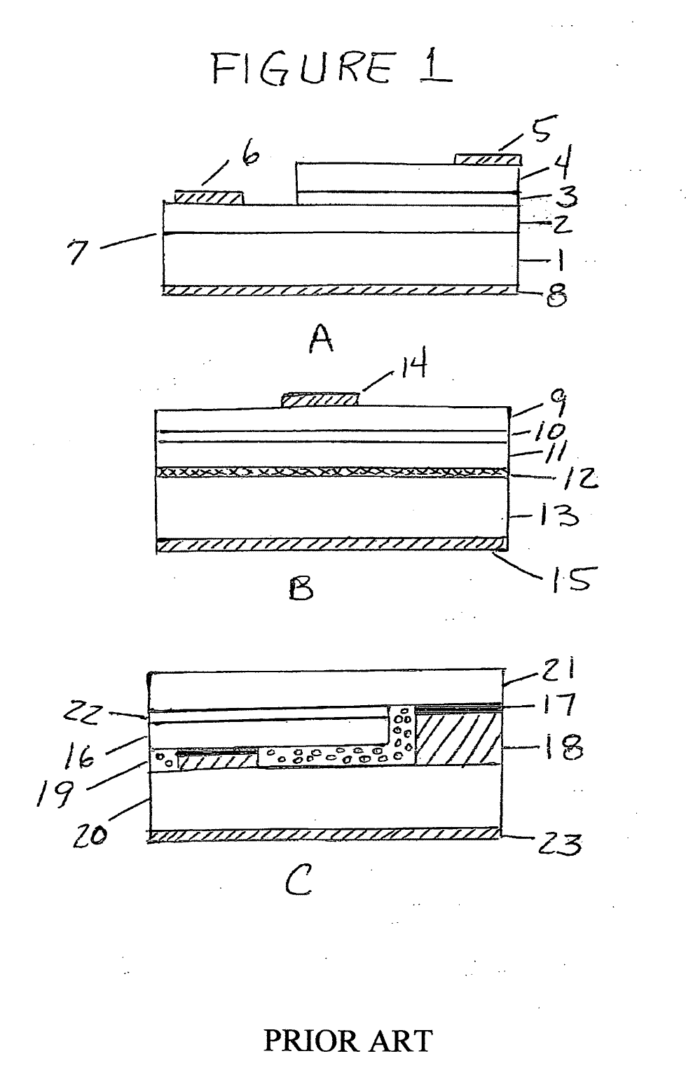

Prior art FIG. 1 depicts the standard LED die semiconductor structures presently used in the industry. Prior art FIG. 1A depicts a 3 micron thick coplanar nitride LED on a 200 micron thick sapphire substrate 1 with die attachment means 8, which typically consists of a reflector, with or without a die attachment layer, such as a eutectic solder for bonding the LED to a heatsink or other submount not depicted in the drawing. The interface 7 between the thin sapphire substrate 1 and the adjacent nitride layer 2 may or may not be textured for enhanced crystal quality and extraction. The interface 7 creates a thermal impedance boundary resistance, which can be larger than the thermal impedance of the thinned sapphire substrate 1 itself. The use of more exotic growth substrates including, but not limited, to AlN, SiC, diamond, and silicon, all create nearly identical thermal boundary resistances due to lattice mismatch and its effect on phonon reflections, even though epitaxial growth is used. The reflection of phonons at this interface creates this effect because of the mismatch between thin sapphire substrate 1 and adjacent nitride layer 2. This boundary resistance then determines the operating temperature of the active region 3 between nitride layers 2 and 4. This creates essentially a phonon cavity around the active region trapping heat in the active region. Increased heating of the active region adversely effects emission, mobility and other semiconductor properties for LED, RF and power devices. In a coplanar LED, contacts 5 and 6 are created on nitride layers 4 and 2 respectively. Light is emitted from the active region 3 through the nitride layer 4. The use of outer surface texturing on the outer nitride layer 4 is typically used to enhance emission from the LED.

Prior art FIG. 1B depicts the typical structure of a vertical LED device. In this case, submount 13 typically consists of Silicon, Germanium, metal composite, diamond, AN, or some other high thermal conductivity material with a good thermal expansion match to the adjacent thin nitride epitaxial layer 12. In this vertical configuration, the submount 13 must exhibit sufficient electrical conductivity or a via method must form the connection between nitride layer 11 and die attach means 15. Die attach means 15 typically consist of a eutectic solder.

Wafer bonding layer 12 is typically a higher temperature solder than die attach means 15 to prevent damage during die attach, with multiple metallization layers to provide an adhesive connection and an electrical connection between nitride layer 11 and die attach means 15. A higher temperature solder than will be used for subsequent die attach is typically required to allow for eutectic bonding of die attach means 15 without effecting wafer bonding layer 12 as the thin epitaxial nitride layer 11 lacks the structural integrity to be handled in a freestanding manner. Wafer bonding layer 12 introduces thermal impedance to this type of device but it also creates problems with subsequent wirebonding steps to contact 14. The fragile nature of the thin epitaxial nitride layer 11 mounted onto a pliable wafer bonding layer 12 dictates that low bonding pressure are required to create the connection. This low bonding pressure compromises long term reliability and yield for the entire semiconductor structure device.

Prior art FIG. 1C depicts a typical flip chip semiconductor structure on a submount device. Submount 12 submount 20 in the figure typically consists of a dielectric material due to the need for embedded or surface interconnects for subsequent packaging levels. Die attach means 23 allows for attachment of the LED to heatsinks and other levels of interconnect or cooling not shown in the drawing. Submount 20 is typically larger than the emitting area of the LED itself due to packaging, interconnect and assembly requirements as known in the art. Solder balls 18 and thin epitaxial contacts 17 electrically and thermally connect the thin epitaxial layer consisting of nitride layers 16, 22, and 21 to the submount 20. Nitride layers 16, 22, and 21 typical exhibit a total thickness of 3 microns and are additionally supported by underfill 19. While a limited amount of heat is removed via the underfill 19, its main function is to support layers 21, 22 and 16 mechanically and thermally. This design suffers from poor thermal performance and also mechanical failures, such as cracking of layers 21,22 and/or 16 due to thermal mismatch issues especially at high power densities.

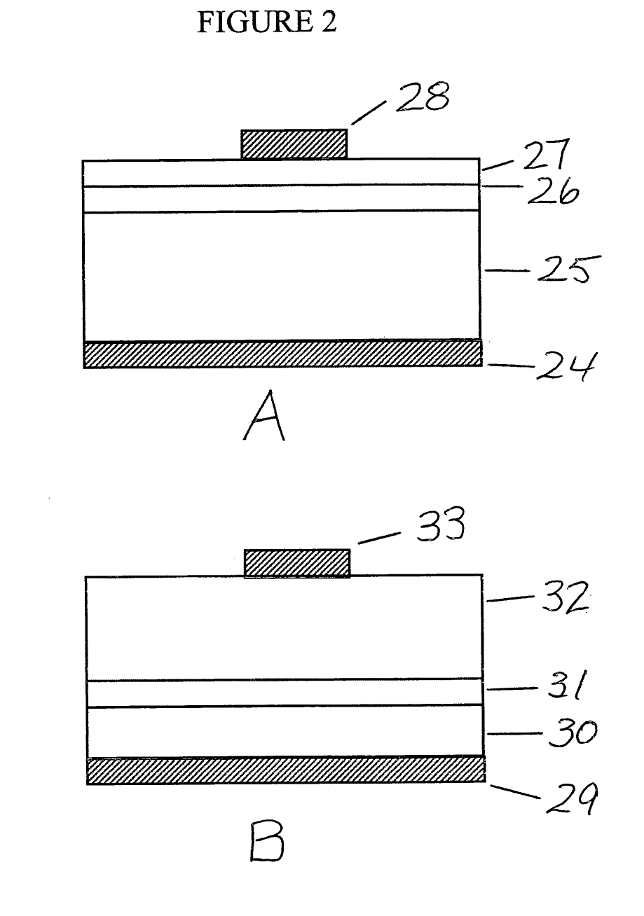

FIG. 2 depicts an all nitride epitaxial chip as disclosed in this invention. P contact up and p contact down vertical devices are shown. Flip chip configuration are also embodiments of this invention.

FIG. 2A depicts a p contact up vertical semiconductor structure device. This device could be an LED, RF device, power HEMT, or other semiconductor device. A LED is used for illustration. Die attach means 24 may consist of, but not limited to, reflective layers, adhesion layers, solder layers (including eutectic solders) used to attach the die to heatsinks and/or other support and interconnect means not shown depicted in the figure. The device has the die attach means 24, a thick doped nitride layer 25, an active region 26 for the emission of light, a doped nitride layer 27 and an upper electrode 28. This is a vertical structure such that current flows between top contact 28 and die attachment means 24. The thick nitride layer 25 is preferably greater than 10 microns for large power devices and has a thickness to width ratio less than 4 to 1 for distributed micro chips used in large area lighting and displays as discussed in other filings by the authors of this present invention. The thick nitride layer 25 is most preferably n doped continuously throughout the layer. However, the use of gradient doping and step doping of the thick nitride layer enhances the properties of current spreading, crystal quality and optical properties. Most preferably, thick nitride layer 25 exhibits resistivity less than 1 ohm cm. Even more preferably thick nitride layer 25 exhibits resisitivity less than 1 ohm cm and average alpha less than 1.0 cm⁻¹ at the emission wavelength of the device.

Alloys, such as AlGaN, can shift the optical properties of the thick nitride layer 25 to minimize the optical absorption coefficient alpha within the emitting wavelength range of the device. The use of thick nitride layer 25 enhances the incorporation of the indium during growth of active region 26. It has been demonstrated that use of thick nitride layer 25 in subsequent growths can allow for higher percentage indium concentration in InGaN layers as would be used to create MQWs, SQWs, DHJs, and SHJs. Using thick nitride layer 25 as a growth substrate, high quality InGaN with greater than 40% indium has been demonstrated for active region 26. In addition, increased growth rates have been demonstrated relative to thinner MOCVD and HVPE templates. More preferably, the use of HVPE templates with thickness greater than 10 microns enhances the crystal quality of InGaN with greater than 20% indium composition. Preferably, the formation of InGaN has indium concentration greater than 20%.

Active region 26 may include, but is not be limited to, single heteroj unction, double heterojunction, quantum dot, single quantum wells, and multiple quantum wells, with or without photonic and superlattice structures for directional and/or enhanced light extraction. The formation of edge emitting and laser diode structures can take advantage of the cleavable nature of the all nitride epitaxial chip.

Upper doped layer 27 may consist of, but is not be limited to, p type materials such as GaN, AlGaN, AlN, ZnO, BN, and diamond. The layer 27 can be grown either totally by HYPE or via other deposition methods including, but not limited to, MBE, MOCVD and laser ablation. Layers 25, 26, and 27 can be textured by photochemical etching, mechanical means, laser etching and other etching techniques. Most preferably HVPE can grow thick high quality p layers for reduced optical absorption and increase current spreading.

Current spreading layers including, but not limited to, ITO, AZO, ZnO, NiAu, and other transparent conductive oxides can be positioned between the nitride layers 27 or 25 and the active region 26. The contact 28 can consist of, but is not limited to, a metal, a fired metal composite, or a conductive frit. The use of a high temperature firing or curing step is enabled by the all nitride nature of the epitaxial chip to create contact 28 and/or die attach means 24. More preferably the formation of these contacts within a controlled atmosphere during firing is an embodiment of this invention.

Printed electronics, passive and active, can be formed on the top surface of layer 27 in addition to the contact 28. These printed electronics can be used to form addressing, monitoring, or protection means both in inorganic or organic systems. In this manner, additional functions can be integrated into the device. High temperature deposition, annealing, curing, and annealing steps are enabled by the high temperature nature of the epitaxial chip for devices and other functional elements including, but not limited to, capacitors, inductors, resistors, luminescent layers, energy storage elements, and active semiconducting elements.

FIG. 2B depicts a p contact down semiconductor structure device in which die attached means 29 is in ohmic contact with p-doped nitride layer 30, followed by active layer 31 for the emission of light, and thick n-doped nitride layer 32 to which upper contact 33 is attached. Current flows between upper contact 33 and die attached means 29. In this configuration, the relatively thin p nitride layer reduces the thermal impedance path to the cooling means for heat generated within the active region 31. In LED applications, the use of low alpha material in layers 30 and 32 is critical to create high extraction efficiency in thick nitride layers. More preferably the average alpha is less than 10 cm⁻¹. Embodiments disclosed in FIG. 2A also apply to this device configuration. Coplanar structures for flip chip and embedded chip applications can also be formed.

Transparent electrodes can be used for either contact 33 or die attach means 29 for embedded applications such that additional interconnect means for external devices through the contacts can be attached, deposited, or grown. The high temperature nature of the epitaxial chip allows its incorporation into glasses, solgels, and other inorganic binders to form arrays of chips. More preferably sintering, melt bonding, drying, deposition steps below 1100 degrees C. can be used for this semiconductor structure device. The use of this ability to process the epitaxial chip or assemblages of epitaxial chips at these elevated temperatures is a preferred embodiment of this invention. Even more preferably, high temperature bonding materials such as glasses and frits are used to form stacks and/or arrays of epitaxial chips and luminescent elements. The use of high temperature processes enables improved electrical and device performance due to the formation of better ohmic contacts and the formation hemetic or improved moisture barriers. The use of higher thermal conductivity materials are also enabled by the use of high temperature processes. The use of these high temperature processes in conjunction with any of the disclosed surface modification or enhanced indium composition is also an embodiment. In both these cases, the resulting devices are substantially all-nitride. Unlike the devices depicted in FIG. 1, the devices depicted in FIG. 2 do not have either a growth substrate or non-native support means associated with the device.

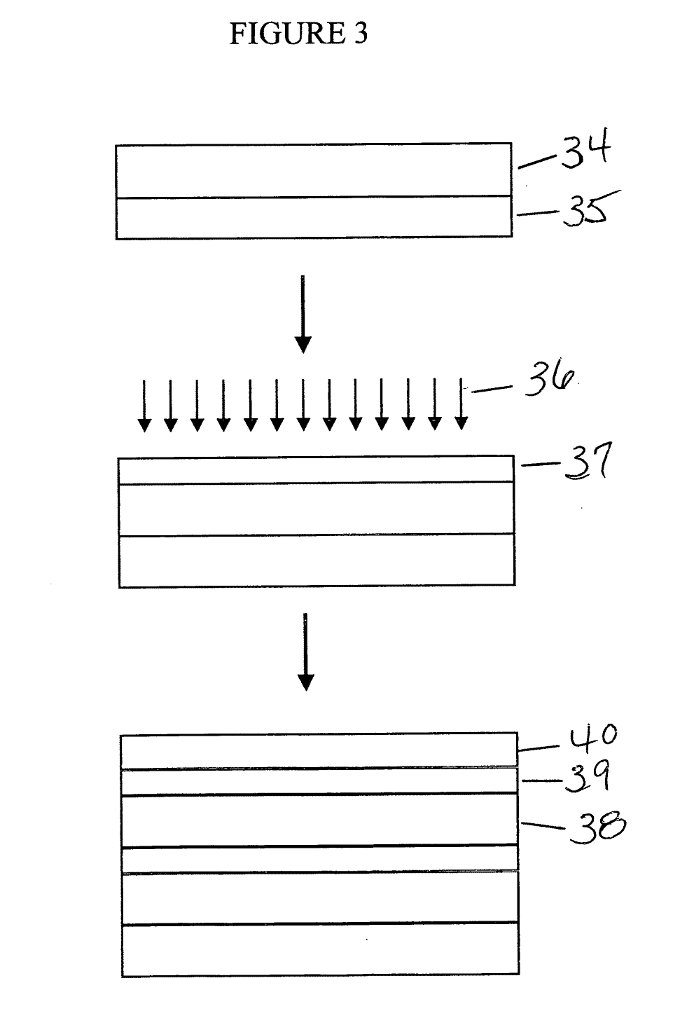

FIG. 3 depicts a method of growing an epitaxial wafer, tape, ribbon, fiber, foil or sheet suitable for the formation of the devices described in FIGS. 2A and 2B. The first step in the process involves the formation of growth layer 34 on a growth substrate 35. Preferably growth substrate 35 would be transparent to radiation used for removal of at least a portion of growth layer 34 via laser liftoff. Alternately, a nucleation/release layer such as nanowires, strain sensitive layers, and dissolvable layers can be used to allow for formation of the freestanding epitaxial chips. All subsequent growth and processing steps may occur prior to or after removal of the growth substrate 35. Most preferred is the removal of growth substrate 35. The growth layer 34 may consist of, but is not limited to, n and p doped materials, semi-insulating materials, and undoped materials. More preferably, the growth layer 34 would consist of nitrides formed by HVPE. Even more preferably, the growth layer 34 would be more than 10 microns thick for large area power devices and have a thickness to width ratio less than 4 to 1 for micro epitaxial chips as used in distributed arrays for general illumination and displays.

The next step may consist of, but is not limited to, the use of actinic radiation, diffusion, and etching methods 36 to modify the surface of the growth layer 34. More preferably surface features are formed to enhance crystal quality, light extraction, and the surface area of any subsequent growths Preferably, the use of these techniques increases the surface area onto which any subsequent growth is grown. Since most subsequent growths including, but not limited to, SQWs, MQWs, HEMTs, semi-insulating layers, and quantum dots exhibit thicknesses less than 1 micron, a surface profile on growth substrate 34, with feature sizes greater than the thickness of any subsequent growth layer, will exhibit higher surface area than the same subsequent growth layer on a flat surface. More preferably, laser etching techniques including, but not limited to, DPSS, excimer, and IR laser sources are used to trench, pattern, and/or recrystallize growth layer 34 in a region defined as modification layer 37. The depth of this modification is sufficient to increase the emitting surface area of any subsequent growth layer. Alternately, the formation of feature less than 10 microns with width to depth aspect ratios greater than 1 to 1 can be readily formed using lasers. Preferably the depth of the modification to less than half the thickness of growth layer 38

In this manner, lasers cut high aspect ratio trenches or features such that lateral growth can be used to improve crystal quality. More preferably, the use of lasers with at least one dimension less than 10 microns may be used to texture the surface of growth layer 34. The use of lasers to modify the surface of growth layer 34 is preferred, due to the laser's ability to spatially raster line, spot, and imaged radiation through the use of stages and/or galvos. In addition, the flux density is sufficient to create very high aspect ratio features even through 100 micron thick layers. The ability to generate these features quickly and in wide range of shapes enables access to a number of different crystal planes. The subsequent growth of growth layer 38 can be such that lateral epitaxial growth techniques as known in the art can be used to improve crystal quality of growth layer 38. In addition, the formation of extraction embedded extraction elements can be created for enhanced device performance.

Additionally, post processing techniques including, but not limited to, plasma cleaning, chemical etching, reactive ion etching, and other removal means can remove residue and damaged crystal regions in the processed nitride layer. Lithography and etching means as known in the art can create surface features with depth to thickness ratios significantly less than those created by laser techniques. These features can consist of, but are not limited to, gratings, photonic lattices, and anisotropic etch features. These are all surface modifications useful for LEDs and lasers. The use of these features creates extraction elements and directional elements within the device itself.

The next step would typically involve the further growth of a doped layer 38, active layer 39 and doped top layer 40. These layers may consist of n type, p type, semi-insulating, and undoped materials as known in the art to create a particular semiconducting device. Alternate materials such as ZnO, AlGaN, MN, diamond, silicon, and various oxides can form devices on the thick epitaxial layer 34 as known in the art. Epitaxial chips for light emitting diodes, RF devices, solar cells, and power devices can benefit from the thermal and electrical impedance properties of the epitaxial layer formed by the present invention. Subsequent liftoff via laser, strain release layer, or etching approaches can remove growth substrate 35 if growth substrate 35 was not removed prior to any of the previous steps.

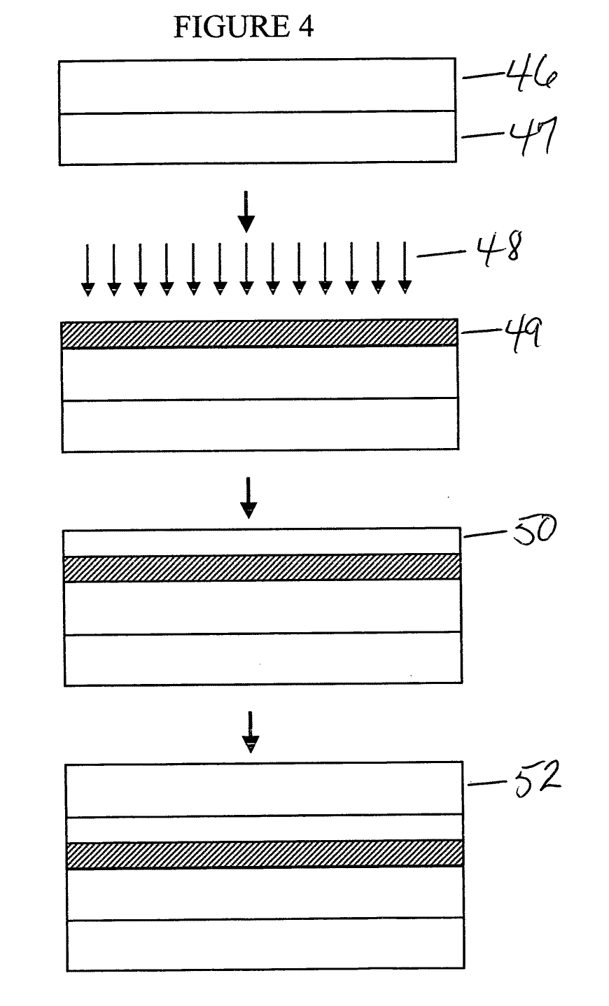

FIG. 4 depicts a method of growing an epitaxial wafer with internal surface modification between growth stages. Growth layer 46 is epitaxially grown on growth substrate 47 by LPE, HVPE, MOCVD, or MBE. More preferably, HVPE is used to grown the layer 46 on the substrate 47

Growth layer 46 is modified by modification means 48 which may consist of, but are not limited to, laser, etching, mechanical ruling, and grinding techniques.

Additional cleaning steps can remove residue and damages layers via etching. In this manner modified layer 49 may be formed. In this example, growth layer 47 is 30 microns thick, uniform n doped, GaN.

A mechanical ruling technique forming a submicron grating surface as known in the art will create modified layer 49. A chemical etch using dilute HCL solution can remove debris and damage of the modified layer 49.

In the next step, active region 50 is deposited via MOCVD. The active layer may consist of, but is not limited, to a MQW, SQW, DHJ, or SHJ of InGaN. The composition and thicknesses of the structure within the active region as known in the art are dependent on the final device performance required.

In the last step, a top layer 52 is deposited via HVPE and may consist of, but is not limited, to a Mg doped AlGaN barrier, Mg doped GaN contact, and a p doped ZnO or ZnMgO spreading layer. The use of additional layers to create devices and the modifications of the various layers using the methods described above are embodiments of this invention. The resulting wafer, its use as a growth template, and the resulting devices are embodiments of this invention.

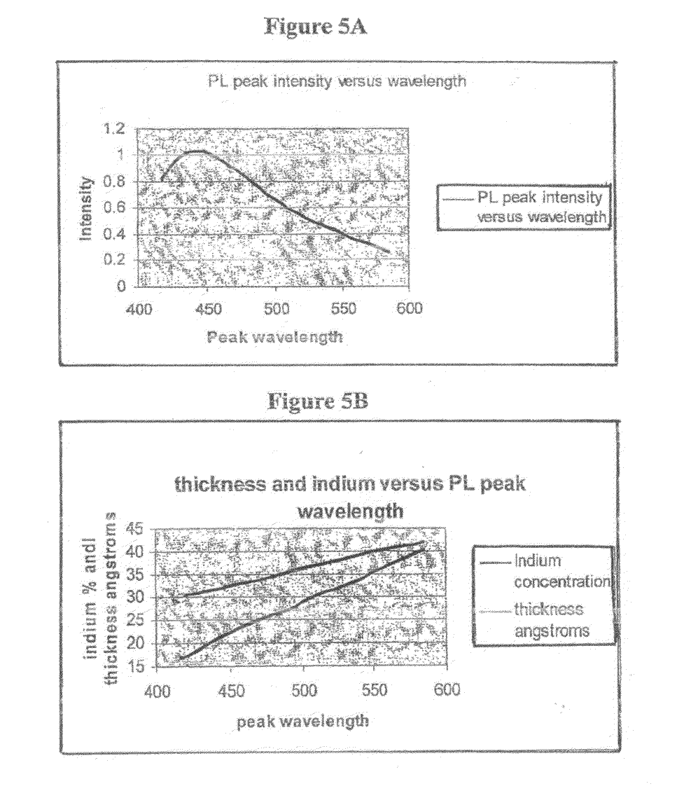

FIG. 5A depicts a PL graph of output versus wavelength for a 5 period MQW grown on a 30 micron thick HYPE template in which the temperature across the wafer was varied such that the indium composition varied from 17% to 40% within the quantum wells. The quantum well barrier were undoped GaN as reference. The structure was optimized for maximum PL at 460 nm. The ratio of PL output at 585 nm is ⅕ the level of the PL at 460 nm. This will be called the relative PL ratio.

FIG. 5B depicts both the thickness of the quantum wells and indium concentration as a function of wavelength that were used to create the curve in FIG. 5A. FIG. 5A illustrates the improved output of wavelengths greater than 500 nm using thick HVPE templates. While efficiency does drop going from blue to red wavelengths, the amount of drop is less than half the expected roll off reported in the literature. But the ratio of blue to red PL clearly indicates that the longer wavelength emission is enhanced.

In addition, FIG. 5B depicts that the thickness of the quantum well increasing at a much smaller rate than the indium concentration is increasing. As such, the efficiency of the MQWs at longer wavelength is expected to be less due to increased confinement losses and less than optimum structure. This is further indication that that the ratio of blue to red PL emission can be reduced using this thick HVPE template approach. An embodiment of this invention has an LED grown on thick HVPE template emitting between 500 nm and 800 nm exhibiting a relative PL ratio greater than derived from the curve shown in FIG. 5A. While this region is relative the blue PL, internal quantum efficiencies have been reported greater than 80% between 400 and 480 nm. As such, very little improvement can be expected in the blue region and a relative PL ratio can be described which is ratio of the PL of the wavelength of interest and the PL of the emission between 400 and 460 nm. The present inventors have demonstrated that thick HVPE templates can be used to increase the relative PL ratio over the wavelength range of 500 to 800 nm. It is also an embodiment of this invention that thick HVPE templates enable the growth of layers with thickness greater than and at indium levels greater than the curves shown in FIG. 5B. Even more preferably, is the use of thick HVPE templates to grow LEDS exhibiting PL greater than the curve shown in FIG. 5A containing quantum wells with thickness greater than and at indium levels greater than the curves shown in FIG. 5B.

While the invention has been described with the inclusion of specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

1. A semiconductor structure device having a nitride template with a thickness between 15 and 150 microns.

2. The semiconductor structure device of claim 1 wherein said nitride template is grown via at least one of the following processes, HVPE, MOCVD and MO-HVPE.

3. The semiconductor structure device of claim 2, wherein said nitride template has an alpha less than 1 cm⁻¹ for wavelengths greater than 395 nm.

4. A semiconductor structure device having a nitride template with a thickness between 15 and 150 microns wherein all of the semiconductor layers of said semiconductor structure device are nitrides.

5. A semiconductor structure device of claim 4 wherein said semiconductor structure device is a LED, a RF device, a power HEMT, a solar cell, a power electronic device, or an optoelectronic device.

6. The semiconductor structure device of claim 1 wherein said nitride template exhibits a resistivity of less than 1 ohm-cm and an alpha of less than 1.0 cm⁻¹ at the emission wavelength of said semiconductor structure device.

7. The semiconductor structure device of claim 1 wherein said nitride template is a nitride alloy of one or more of the following elements: Al, In, P, As, Mg, Ga, and B.

8. The semiconductor structure device of claim 1 wherein said nitride template is a growth substrate and at least one subsequent semiconductor layers has greater than 20% indium InGaN

9. The semiconductor structure device of claim 1 wherein said nitride template is flexible.

10. The semiconductor structure device of claim 1 wherein said nitride template is formed by an epitaxial growth process.

11. The semiconductor structure device of claim 1 wherein said semiconductor structure device is a light emitting diode emitting light between 500 and 800 nm.

12. The semiconductor structure device of claim 1 wherein said nitride template has at least one surface feature, wherein said at least one surface feature provides enhanced light extraction, improved crystal quality, or increases the surface area of any subsequent growths.

13. The semiconductor structure device of claim 1, wherein said nitride template has a wafer, tape, ribbon, foil, or fiber form factor.

14. A method of forming a nitride semiconductor structure device comprising
forming a nitride template;
modifying at least one of the surfaces of said nitride template by photochemical etching, mechanical means, laser etching, or other etching means;
epitaxial growth on said at least one of the surfaces of said nitride template using GaN, AlGan, InGaN, InN, AlInN, AlGaInN, MN, ZnO, Si, SiC, SiGe, InSb, GaSb, ErSb, or diamond;
deposition of a current spreading layer on said at least one surface of said nitride template; and
formation of printed electronics on said nitride template.

15. The method of forming a nitride semiconductor structure of claim 14 further comprising
epitaxial growth on said at least one of the surfaces of said nitride template of an active region of SQWs, MQWs, DHJ, SHJ, Quantum Dots, or PN junctions; and
subsequent growth in a separate reactor of barrier and p layers of said a nitride semiconductor structure;
wherein said nitride semiconductor structure is a light emitting diode.

16. The method of forming a nitride semiconductor structure of claim 14 further comprising
epitaxial growth on said at least one of the surfaces of said nitride template of an active region of SQWs, MQWs, DHJ, SHJ, Quantum Dots, or PN junctions; and
subsequent growth in a separate reactor of a lower bandgap solar cell junction of said a nitride semiconductor structure;
wherein said nitride semiconductor structure is a multi junction solar cell.
